(19) United States
(12) Patent Application Publication
(10) Pub. No.: US 2005/0038143 A1
(43) Pub. Date: Feb. 17, 2005

(54) Photoresponsive polymer systems and their use

(76) Inventors: Shlomo Yitzchaik, Jerusalem (IL); Eugenia Vaganova, Jerusalem (IL); Vladimir Khodorkovsky, Beer-Sheva (IL)

Correspondence Address: NATH & ASSOCIATES, 1030 15th STREET, NW, 6TH FLOOR, WASHINGTON, DC, 20005, US

(21) Appl. No.: 10/488,357

(22) PCT Filed: Sep. 4, 2002
(86) PCT No.: PCT/IL02/00737

Related U.S. Application Data
(60) Provisional application No. 60/316,278, filed on Sep. 4, 2001.
(60) Provisional application No. 60/402,530, filed on Aug. 12, 2002.

(51) Int. Cl. C08L 1/00

(52) U.S. Cl. 524/99

(57) ABSTRACT

The present invention provides an organic composition comprising a water-soluble heteroaromatic compound, water and a polymer containing repeat units derived from six-membered aromatic heterocyclic monomers substituted in the 4-position relative to the heteroatom by an alkyl substituent, said six-membered aromatic heterocyclic monomer optionally being further substituted. The organic composition is excitable by predetermined incident electromagnetic radiation of predetermined intensity such that the excitation of a location of the composition by the predetermined incident radiation creates at least one of the following effects: a desired luminescence of the excited location and a desired electrical conductivity of the excited location.

### FIELD OF THE INVENTION

The present invention is generally in the field of photoresponsive polymeric systems.

### LIST OF REFERENCES

The following references are considered to be pertinent for the purpose of understanding the background of the present invention:

(1) H. Hong et al, Thin Solid Films 366, 260-264 (2000);

(2) W. Jessen et al, Synth. Metals 84, 501 (1997);

(3) E. Vaganova et al, “Photoinduced structure changes in Poly (4-vinyl pyridine): a luminescence study”; Journal of Fluorescence 10, 2, 81-88, (2000);

(4) U.S. Pat. No. 5,272,234;

(5) Vaganova, E., Yitzchaik, S. “Photoinduced reversible cross-linking in polymeric matrices”, Pol. Mat. Sci. Eng. 84, 1089-1090, 2001;

(6) Vaganova, E., Rozenberg, M., and Yitzchaik, S. “Multicolor Emission in Poly(4-vinyl-pyridine) Gel”, Chemistry of Materials, 2000, 12, 261-263;

(7) Rozenberg, M., Vaganova, E., and Yitzchaik, S., “FTIR Study of Self-Protonation and Gel Formation in Pyridinic solution Poly(4-vinyl pyridine)”, New Journal Chemistry, 2000, 24, 109-111; and

(8) Vaganova, E. and Yitzchaik, S. “Tunable emission in Poly(4-vinyl pyridine)-based Gel”, Acta Polym., 1998, 49, 632-637.

### BACKGROUND OF THE INVENTION

Polymers with tunable optical properties that may be varied in predictable ways are of great interest for practical applications, e.g. optical storage and retrieval devices.

One way to vary the optical properties of a polymer is to change its chain packing order. Optical properties of pyridine-containing polymers are well known as morphology-dependent. The promotion of lone-pairs electrons to backbone results in the broken charge conjugation symmetry. For example, the photoluminescence of pyridine-containing polymers, poly(p-pyridine) and poly(p-pyridyl-vinylene), was red shifted in thin film compared to that in solution (W. Jessen et al, (1997)). Interchain interactions in the film lead to the distribution of electrons over wider parts of the molecule than in solution. Such delocalization causes a reduction of the band gap and consequently the photoluminescence is shifted to longer wavelengths.

A recent study (E. Vaganova et al, “Photoinduced structure changes in Poly (4-vinyl pyridine): a luminescence study” Journal of Fluorescence 10, 2, 81-88, (2000) teaches a manner of controlling photoluminescence properties in a system based on poly(4-vinyl pyridine) (hereinafter “P4VPy”). In this study, concentrated solutions of P4VPy dissolved in pyridine turned into gel under UV-irradiation, specifically, at 380 nm. This phase transition results in changes in the optical properties of this polymer. In the absorption spectrum, a new absorption appeared in the visible range, and the position of the photoluminescence maximum could be changed continuously from 440 nm to 480 nm during irradiation. Solutions of P4VPy in pyrimidine showed similar behavior. It was also observed in that study that the process of photoinduced sol-gel transformation is reversible: mechanical perturbation or heating could convert the gel back to a fluid solution.

Well-known photochemical reaction is pyridine cleavage. Under UV-irradiation at 250 nm wavelength pyridine in the presence of water undergoes photoisomerization to a Dewar pyridine. As the reaction continues, 5-amino-2,4-pentadienal (AP) is produced. AP absorbs at 364 nm and reverts in the dark to pyridine with water elimination (Joussot-Dubien, J. Tetrahedron Letters, 1967, 44, 4389-4390; Andre, J. C.; Niclause, M.; Joussot-Dubien, J.; Deglise, X. J. of Chemical Education, 1977, 54, 387-388; Wiltzbach, K. E.; Rausch, D. J. J. Am. Chem. Soc., 1970, 92, 2178-2179).

Organic light emitting diode (OLED) devices based on self-assembled P4VPy with poly(N-vinyl carbazole) and 2-(4-biphenyl)-5-(4-tert-butylphenyl)-1,3,4-oxidiazole was reported (H. Hong et al, (2000)).

The main principle of conductivity is supposed to be an electron conduction, which occurs through the extended π-conjugation. Conjugated conductive polymers, which are photo-responsive upon ultra-violet or visible light irradiation, are described in U.S. Pat. No. 5,272,234. The conductive polymers are prepared from copolymerization of photo-responsive groups containing heterocyclic monomers and 3-substituted heterocyclic monomers with the substituent containing a flexible segment like an alkyl group, ethoxyl group or siloxane group. The conductivity of these polymers can be controlled reversibly by irradiation of light.

### SUMMARY OF THE INVENTION

There is a need in the art to facilitate inducing of luminescence into selective locations in an initially non-luminescent material in a reversible manner, as well as enable inducing electrical conductivity of selective locations in an initially non-conductive material, by providing an organic composition and a method of treating this composition to provide the desired properties thereof.

The present invention relates to an organic composition that is responsive to incident electromagnetic radiation of a predetermined wavelength such that energy bands defining a certain energy gap are created in an irradiated location of the composition thereby defining the luminescence and/or electrical conductivity of the irradiated location.

Thus, according to one aspect of the present invention there is provided an organic composition comprising a water-soluble heteroaromatic compound, water and a polymer having repeating units derived from six-membered aromatic heterocyclic monomers substituted in the 4-position relative to the heteroatom by an alkyl substituent, said six-membered aromatic heterocyclic monomer optionally being further substituted, the organic composition being excitable by predetermined incident electromagnetic radiation of predetermined intensity such that the excitation of a location of the composition creates at least one of the following effects: a desired luminescence of the excited location, and a desired electrical conductivity of the excited location.

The water-soluble heteroaromatic compound is selected from: pyridine, substituted pyridine, pyrimidine, nicotine, quinoline, bi-pyridine, derivatives of these compounds and mixtures thereof. More preferably, the compound is pyridine. The polymer may be optionally substituted poly(4-vinyl pyridine), poly(diallyldimethylamonium) chloride, poly(4-vinyl quinoline) or co-polymers thereof, preferably poly(4-vinyl pyridine). The molar ratio between the polymeric units, the water-soluble heteroaromatic compound and water is preferably about 1:1:(0.3-1).

By appropriate radiation of a location in the composition (where the term “appropriate” relates to a certain wavelength of UV-radiation, intensity, and duration), the irradiated location can be shifted from a stable initial state (substantially of only blue luminescence) into a new, active state of desired luminescence, and can be either returned into the initial state or to another state of a different luminescence by a further application of electromagnetic radiation of a predetermined wavelength to this location. Irradiation of a selected location of the composition can shift this location from its passive state (where the term “passive state” used herein denotes a state of substantially low-conductivity) into an active stable state of a desired electrical conductivity. The conductivity may be tailored by choice of the wavelength of the incident electromagnetic radiation, as well as the intensity and/or duration of the irradiation in each selected wavelength, so that the composition may be used as a semiconductor having a conductivity in the range from 10⁻⁶ to 10⁻³ S/cm. Typically, the passive, low-conductive state has a conductivity of between 10⁻¹⁰ to 10⁻⁸ Scm⁻¹.

The intensity and duration of the irradiation in each wavelength can be varied, and a wide range of durations and intensities are suitable for reversion between the passive and active states. There exists a reversed relationship between the duration and the intensity: the longer the irradiation the lower the intensity needed to obtain the desired luminescence/conductivity, and vice versa. By using a high-frequency laser radiation, the state of the irradiated location can be changed during one pulse of radiation (about 10⁻⁶ sec).

The term “stable” in the context of the present invention, means that the composition of matter maintains its lumninescent/conductive (generally, excited) properties essentially unaltered, for prolonged periods of time. Preferably, the organic composition of the present invention maintains each new electronic state for a period of at least half a year.

The inventors have found now that irradiation of the P4VPy/pyridine/water system with 250 nm leads, in addition to the absorption band centered at 360 nm with a shoulder at 400 nm, to a new red-shifted emission at 515 nm, and a weak absorption in the visible (500-600 nm) and near IR ranges.

In other words, upon continuation of radiation at 250 nm, together with an increase of the intensity of the absorption peak at 360 nm, a prolonged tail through the whole visible range was observed. Lower energy luminescent species are formed, and it is believed that among these species are pyridine open form photoproduct aggregates, such as polyazaacetylene (less than 1% judging from the intensity of the absorption in the ranges 500-600 nm and 800-1400 nm). The presence of lower energy aggregates leads to polymer morphology changes. Short-range aggregates enhance polymeric units interaction, while long-range aggregates have a tendency to crystallize forms similar to the comb-shaped polymers. Also, depending on the polymer/liquid ratio, micelle-like forms with the domain size over 200 nm and nanocrystals with average size at 20-30 nm are formed.

The subsequent irradiation with 360 nm reverts the system into its passive, substantially blue luminescent state.

Upon irradiation with 250 nm, the activation energy of the pyridine ring cleavage and back reaction was evaluated as a function of the polymer/pyridine/water ratio. Activation energy of the pyridine ring cleavage in viscous polymeric solutions is in the range of 0.6-4.0 Kcal/mol, depending on the pyridine concentration. The value is lowered with increase of pyridine concentration. Activation energy of the back reaction is significantly lower and is in the range of 0.05-0.15 Kcal/mole.

When the P4VPy/pyridine system is irradiated with 380 nm, new electronic states with lower energy band gap are formed, and as a consequence—new red-shifted emissions appear. The initial stage of the photochemical reaction consists of the interaction of pyridinium ion, which appears in the system after polymer dissolution, with pyridine molecules to thereby form poly-(4-vinyl pyridinium/pyridine).

By applying UV-radiation of 250 nm or 380 nm to a film comprising the P4VPy/pyridine composition located between two spaced-apart electrodes, a conductive layer can be created in the composition. The effect of the exciting wavelength causing the desired conductivity of the film also depends on the film thickness. The so-obtained conductive locations have conductivity of at least 3-5 orders of magnitude greater than the conductivity in the same location before irradiation.

The present invention further provides a method for treating an organic composition comprising a water-soluble heteroaromatic compound, water and a polymer containing one of repeating units derived from six-membered aromatic heterocyclic monomers substituted in the 4-position relative to the heteroatom by an alkyl substituent, said six-membered aromatic heterocyclic monomer optionally being further substituted, the method comprising:
(i) providing a viscous mixture of the constituents as defined above;
(ii) irradiating at least a selected location of said viscous mixture with ultra-violet radiation having a predetermined intensity so as to cause excitation in the irradiated location of said mixture to thereby obtain at least one of desired luminescence or desired electrical conductivity of the irradiated location.

The invention also provides similar methods for obtaining similar products, wherein the pyridine is replaced or is in combination with another water-soluble heteroaromatic compound having an even number of atoms in the ring, at least one of which is a nitrogen, for example substituted pyridine, pyrimidine, nicotine, quinoline, substituted quinoline, and bi-pyridine.

According to another aspect of the present invention, there is provided an optical device comprising a cell containing an organic composition comprising a water-soluble heteroaromatic compound, water and a polymer containing repeat units derived from six-membered aromatic heterocyclic monomers substituted in the 4-position relative to the heteroatom by an alkyl substituent, said six-membered aromatic heterocyclic monomer optionally being further substituted, said cell being shiftable between stable states of different responses of said composition to predetermined incident electromagnetic radiation.

Such an optical device may be used as an optical switch. Alternatively, the optical device can be used as an information carrier. By appropriately exciting selective locations in the composition with predetermined electromagnetic radiation, a pattern corresponding to specific information to be stored can be recorded in the composition, and can then be read out, as well as erased, if needed, by further excitation of the previously excited (information carrying) locations by a different wavelength of incident radiation. The optical device may include spatially separated regions (e.g., layers) intended for ROM, recordable, and WORM types of memory. To create a luminescent location (the so-called “data region”), wavelengths of about 250 nm (e.g., 250±5 nm) and 380 nm (e.g., 380±5 nm) can be used. To read out the information, wavelengths in the range of about 460-600 nm, e.g., 460 nm, 480 nm, 515 nm, 530 nm and 600 nm, can be used. To remove the luminescence in this location (e.g., erase the data), a wavelength of about 360 nm (e.g., 360±2 nm) can be used.

The composition of the present invention may have further varied utilities, in the construction of structures where it is desired to manipulate (increase/decrease) the conductivity and/or luminescence of a part of the structure by irradiation. Furthermore, the composition of the present invention may be used in various structures where it is desired to be able to reversibly manipulate luminescence of components by irradiation.

One example is electric circuits, which can be produced by coating electrodes transparent to UV-irradiation of 380 nm with the composition of the invention (which is thus located between the electrodes), and then exposing parts of this structure (by known masking techniques) to the irradiation of certain wavelength in order to produce high conductivity, and, if desired, exposing other parts. Generally speaking, the present invention can be used in the following:
optical tunable materials, optical ON/OFF switches;
electrophotography (the composition serving as a photoreceptor, selective irradiation of the composition resulting in recording a required charge pattern therein);
information storage device (selective irradiation of the composition resulting in recording a pattern of data regions indicative of the stored information);
photoinduced non-linear optic device with pyridine open ring photoproduct-5-amino-2,4-pentadienal as a molecule with high hyperpolarizability
Photoswitchable Organic Light Emitting Device (OLED).

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1A schematically illustrates an optical device utilizing the composition of the present invention that can operate as an optical switch or a recordable optical memory device;

FIGS. 1B and 1C exemplify the use of the composition of the present invention in a single-layer ROM device and a multi-layer optical memory device, respectively;

FIG. 2 illustrates the energy schemes of composition sites at initial (not irradiated) state, and the states obtained with two different periods of UV-irradiations;

FIG. 3 shows the absorption spectra in UV/vis/NIR range of poly(4-vinylpyridine)/pyridine/water mixture before and after 120 min UV-irradiation at 250 nm;

FIGS. 4A-4C show TEM images of the polymer gel film (A) before irradiation and after UV irradiation at 250 nm (B and C).

FIG. 5 illustrates the current vs. voltage curve of the poly(4-vinylpyridine)/pyridine/water film before and after UV-irradiation at 380 nm (I(A)-V/mV vs Ag/AgCl electrodes);

FIGS. 6A and 6B show the results of I-V dependence measurement in the poly(4-vinylpyridine)/pyridine/water film (ITO/ITO-electrodes) before and after the application of 380 nm wavelength irradiation, respectively; and

FIG. 7 illustrates two examples of a transistor structure utilizing the composition of the present invention.

### DETAILED DESCRIPTION OF THE INVENTION

The present invention provides a composition comprising a water-soluble heteroaromatic compound, water and a polymer containing repeat units derived from six-membered aromatic heterocyclic monomers substituted in the 4-position relative to the heteroatom by an alkyl substituent (the heterocyclic monomers being optionally further substituted). The molar ratio between the polymer, the water-soluble heteroaromatic compound and water is preferably about 1:1:(0.3-1).

The water-soluble heteroaromatic compound may be pyridine, substituted pyridine, pyrimidine, aqueous solution of nicotine, quinoline, adenine, bi-pyridine, derivatives thereof or mixtures of such compounds. The polymer may be optionally substituted poly(4-vinyl pyridine), poly(4-vinyl quinoline) or co-polymers thereof, preferably poly(4-vinyl pyridine).

Application of UV-radiation to the composition of the present invention causes structural change in the composition. Experiments have shown that the first stage of photosensitive system formation is protonation of the polymeric pyridine and physical interaction with neutral pyridine molecules by hydrogen bonds. With continuation of the irradiation, this interaction is prolonged and the density of the crosslinking increases. Changes of emission properties of the location depend on the intensity and duration of the applied radiation.

A very important feature of the composition of the present invention is that the excited, luminescent location can be reverted to its passive, non-luminescent state by applying UV-radiation of a predetermined wavelength. Experiments have shown that such luminescence-removing wavelength is about 360 nm (e.g., 360±2 nm) with an energy of about 2.6-2.7 mW and more, and excitation time of about 5-20 min.

The above features of the composition of the present invention provide for using the composition as an optical medium in an optical switch, which can be a simple ON/OFF switch, or a tunable switch, since different wavelength responses can be produced by exciting the medium with different wavelengths of incident radiation.

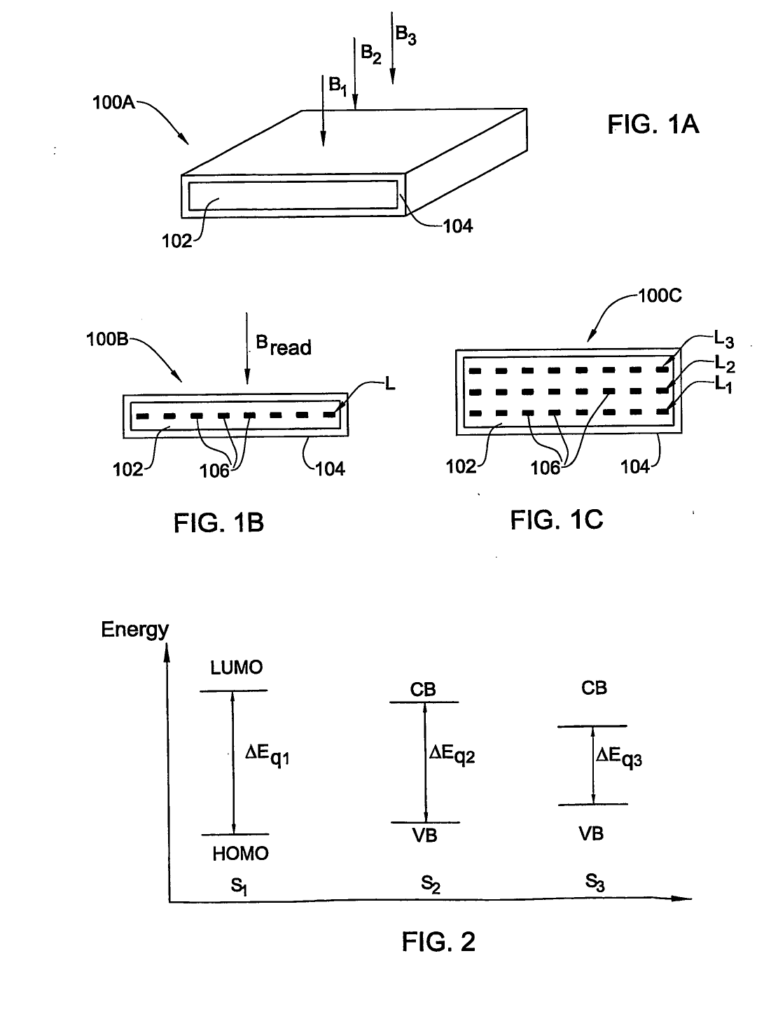

FIG. 1A illustrates a cell 100A containing a layer 102 of the composition of the present invention in a quartz or glass container 104 transparent to predetermined electromagnetic radiation. This cell can be used as an optical device, such as a switch, or an optical memory device where the composition serves as an information carrier. Thus, the device 100A can be a single-layer optical memory device, which may be recordable or WORM (write once read many) memory device. By exciting selective locations in the layer with recoding radiation B₁ of e.g. 250 nm, a pattern corresponding to certain information can be recorded in the composition, and can then be read out by exciting these locations with reading radiation B₂ of e.g., 400 nm, or can be erased by exciting the data regions with 360 nm radiation B₃.

FIG. 1B schematically illustrates an optical memory device 100B, which is a single-layer ROM (read only memory) device having a data layer L formed by the composition of the present invention in a quartz or glass container. The data layer L has spaced-apart data regions, generally at 106, forming a pattern corresponding to the stored information. This pattern has been recorded by applying recording UV-radiation of e.g., 250 nm to the locations 106, and can be read out by applying a different reading radiation B_{read} of e.g., 460 nm.

FIG. 1C schematically illustrates a multi-layer optical memory device 100C, having several vertically aligned information layers—three such layers L₁, L₂ and L₃ being shown in the figure. It should be understood that these layers may be formed by vertically aligning three cells of the composition of the present invention, or by a single cell of a certain suitable thickness, considering the composition is in its semi-solid state. In the present example of FIG. 1C, each layer has spaced-apart luminescent data regions 106 created as described above to form a pattern corresponding to the stored information. To read the information, a reading laser beam is sequentially focused to each of the layers. The first (lower) layer L₁ can be initially irradiated by 250 nm wavelength through the first quartz surface, the second layer L₂ irradiated by 380 nm, and the third upper layer L₃—by refocusing the 380 nm radiation thereto. A glass surface between the adjacent layers can be used for protecting the lower layer from short-UV irradiation. The reading of the information from the different layers can be achieved by irradiating the layers with the same wavelength (e.g., 400 nm), that gives different responses from the layers excited (i.e., irradiated at the data recording stage with different wavelengths, e.g., when using the exciting recording radiation of 250 nm and 380 nm, the 460 nm and 480 nm responses, respectively, can be obtained). The erasing of the image (data) in one of the layers is achieved by focusing 360 nm radiation on the respective layer.

Application of radiation of predetermined wavelength and intensity or duration to the composition of the present invention (at least to one or more locations therein) induces desired electrical conductivity in the irradiated location(s). According to the present invention, the formation of a conducting polymer is achieved by photoinduced arrangement followed by covalent interaction in the polymer system based on pyridine.

FIG. 2 illustrates energy schemes S₁-S₃ of the same sample at different conditions. In the figures, VB is the valence band and CB is the conduction band. Scheme S₁ corresponds to the sample (or location) kept in dark, i.e. no UV-radiation. Schemes S₂ and S3 correspond to the samples (or locations) after, respectively, 30 minutes and 1 hour UV-irradiation. In the present example, the conductivity changes in the sample were achieved by irradiating the sample by a Xenon short ARC lamp with 380 nm wavelength (7 mW) for 30 or 60 min. It should however be noted that by using laser irradiation of a power range of a few Watts, irradiation duration of milliseconds is sufficient to achieve the same results. The effect of increased electrical conductivity induced by UV-radiation can be explained as follows: photoinduced interchain interactions lead to electron density delocalization, and simultaneous decrease of the energy band gap ΔE_{g} of the material with the increase of the crosslinking density.

The following are two examples of preparation of the composition for measuring electrical conductivity thereof induced by incident radiation.

### EXAMPLE 1

1 g of dry poly(4-vinyl pyridine) P4Vpy) (dried under vacuum (10⁻³ torr) at 40-60° C. for one week) was dissolved in 0.8-1.0 ml pyridine/water solution with molar ratio between pyridine and water molecules 0.3:1 in a glass bottle at the room temperature.

The polymer used had a MW of 10000-50000 (Polyscience, Co.). Pyridine high purity (anhydrous 99.8% (Aldrich)) and deionized triply distilled water with pH=6.5-7 were used.

The resultant viscous solution was degassed and placed between two ITO covered glass electrodes for conductivity measurements. The optical density of the ITO electrodes suitable for treatment with 380 nm-radiation is 0.15. The size of the electrodes area, which was covered by polymer's solution was 25 mm×25 mm. To obtain samples with reproducible thickness of 20±5 μm , the two electrodes were pressed by 200 g/cm² and kept under this pressure for 15 min. The polymer solution confined between the electrodes was irradiated for 30-60 minutes by long UV-irradiation centered at 380 nm using Xenon short ARC lamp having energy of 7 mW/cm². The conductivity of 10⁻³ Scm⁻¹ was achieved. The similar value of the photoinduced conductivity can be achieved with more powerful source of UV-light at 380 nm wavelength. The estimation regarding the quantum yield of the photochemical reaction showed that similar conductivity changes can be achieved with laser irradiation (having a power of 5-7 W/cm²) with a duration of millisecond time-scale.

### EXAMPLE 2

1 g of poly(4-vinyl pyridine) (P4Vpy) dried under vacuum (10⁻³ torr) at 40-60° C. for one week was dissolved in 0.8-1.0 ml pyridine/water solution with molar ratio between pyridine and water molecules 1:(0.3-1.0) in a glass bottle at the room temperature. The polymer used had a MW of 10000-50000 (Polyscience, Co.). Pyridine high purity (anhydrous 99.8% (Aldrich)) and deionized triply distilled water with pH=6.5-7.0 were used.

The resultant viscous solution was degassed and placed between two electrodes for conductivity measurements. Cr—Au covered quartz (Nanonics, Co) and ITO covered glass (Delta Technologies) electrodes were used. The optical density of Cr—Au electrodes in the 380 nm wavelength range is 0.6-0.7. The size of the electrodes area, which was covered by polymer's solution, was 25 mm×25 mm. To obtain samples with reproducible thickness of 20±5.0 μm, the two electrodes were pressed by 200 g/cm² and kept under this pressure for 15 min. The polymer film confined between the said electrodes was irradiated by short UV irradiation in the range of 380±5 nm for 1 hour using a Xenon low pressure lamp the conductivity 10⁻⁶ Scm⁻¹ was obtained. When using laser irradiation of the same wavelength with power of several W/cm², similar conductivity changes can be achieved with the irradiation duration of the microsecond scale.

The films prepared in Examples 1 and 2 above are characterized by the photoinduced directional ordering through the charge transfer between pyridine and pyridinium as free as well as bounded. During this photoinduced ordering in comparatively thin layer of the material the conductive channel can be formed.

SHG experiments were performed on thin film (3 μm) poly(vinylpyridine)/pyridine/water samples which were irradiated at 250 nm for 6 hours, dried (10 h, 110° C., 10⁻³ torr) and then corona poled (3.5 kV, 140° C., nitrogen atmosphere, 30 min). The film SHG efficiency was found as corresponding to d_{eff}˜0.1 pM/V, evidencing the formation of nonlinear moieties of cleaved pyridine such as aminopentadienal and polyazaacetylene in the film albeit at a low concentration.

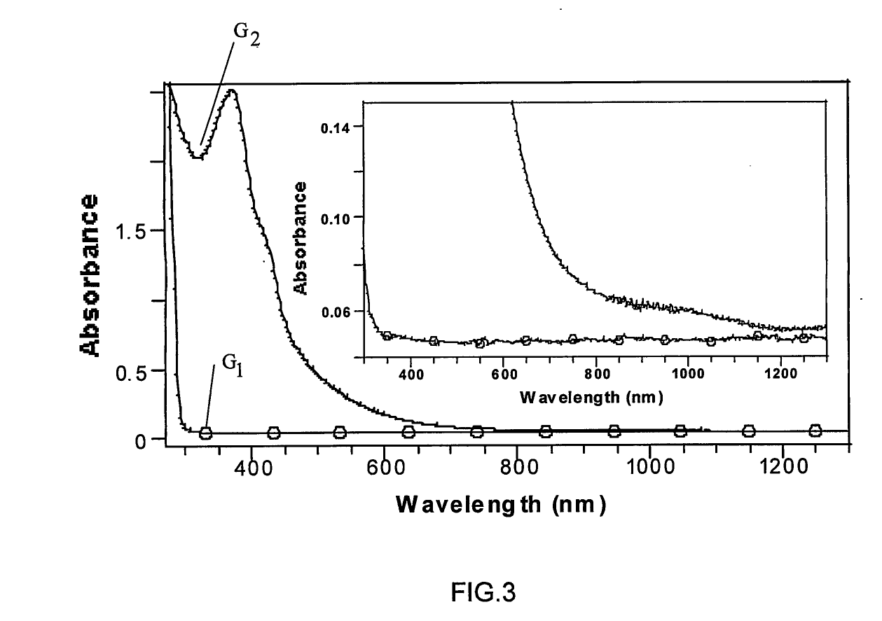

The existence of polyazaacetylene or head-to-tail aminopentadienal organization can be deduced from the absorption spectra of the composition as shown in FIG. 3. Irradiation of viscous films containing poly-(4-vinylpyridine)/pyridine/water mixture (1:1:0.3 molar ratio between poly-(4-vinylpyridine) repeating units, pyridine and water molecules) at 250 nm leads to their partial solidification. The changes can be easily followed by UV/Vis/NIR spectroscopy. Graph G₁ presents the absorption spectrum of the composition prior to being irradiated, and graph G₂ shows the absorption spectra of the composition in the UV/Vis/NIR range after a 120 min irradiation at 250 nm. As shown, a new broad absorption band appeared between 320 nm and 600 nm with a maximum at 360 nm and a shoulder at 400 nm, and another weak absorption band was observed in the visible and near IR range (insert).

The absorption spectra of the P4VPy/pyridine system can be interpreted as follows:
1) the band at 360 nm steams from open form pyridine photoproduct;
2) the shoulder at 400 nm steams from the aminopentadienal moiety;
3) the weak absorption in the visible (500-600 nm) and NIR ranges can be explained by formation of small amounts of polyazaacetylene of formula (I) below, or long-chain aminopentadienal aggregates, or crosslinking through the open form photoproduct interchain interaction: 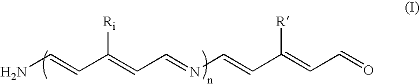
wherein
n is an integer between 2 and 10;
i is an integer between 1 and n; and
the various Rᵢs and R′ are independently H or a vinyl-group of a poly(4-vinyl pyridine) polymeric chain.

Indeed, in a viscous media when aminopentadienal moieties attached to the polymer are brought closely together, linear oligomers can be formed considerably easier than in dilute solutions. Aminopentadienal molecules stemming from pyridine cleavage, can act as cross-linkers.

Quantum mechanical calculations of the spectra of polyazaacetylene of formula I, wherein R′ and Rᵢ are hydrogen and n is between 1 to 5, at the semiempirical ZINDO/AM1 level, showed that energy of the longest wave transition converges when n increases, whereas the energies of the shorter wave transitions undergo red shifts proportional to the n value. The intensity of the longest wave absorption is predicted to be very high for the planar model and drastically diminishes on coplanarity distortion. Although it is difficult to expect coplanarity of monomeric units in a relatively rigid solid polymeric system, the amount of the polyazaacetylene of formula (I) should be small (less than 1%) judging by the intensity of the absorption in the ranges of 500-600 nm and 800-1400 nm.

Irradiation also brings about a gradual shift of emission from 440 nm to 600 nm.

Together with formation of the luminescent aggregates, changes were also observed in the polymer morphology. TEM and calorimetry studies were applied for the polymer morphology investigation.

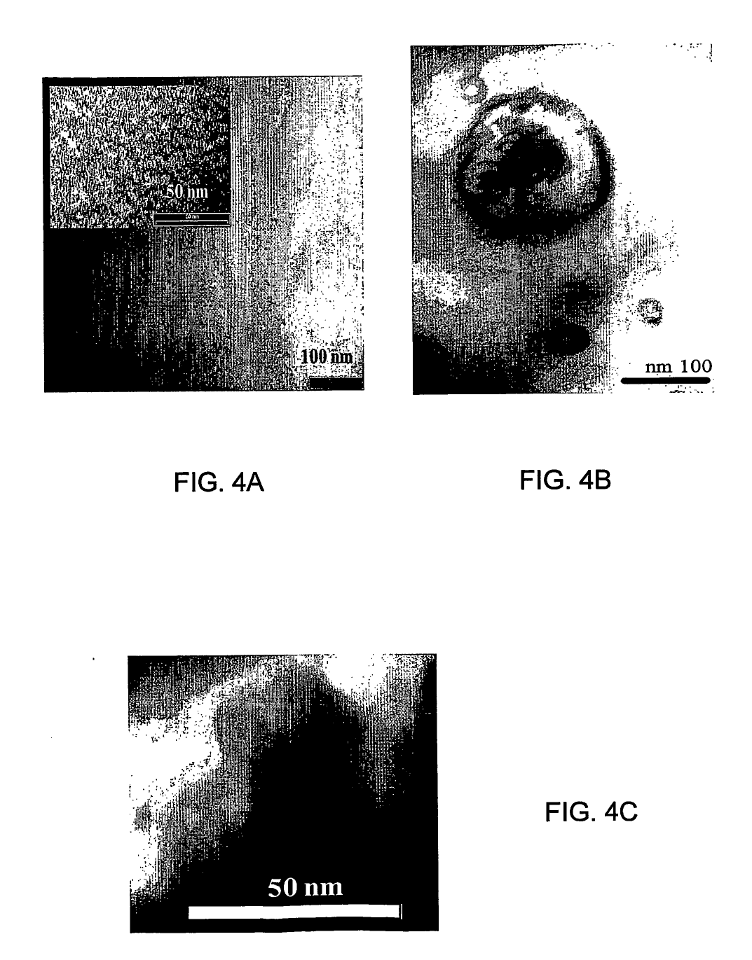

Transmission electron microscopy (TEM) was carried out on samples obtained from the gel thin film before and after irradiation at 250 nm for 60 min. The TEM image of the gel before irradiation is presented in FIG. 4A including insert, in two scales: with low and high magnification, where homogeneous structure of the polymer film is observed. The photoinduced process of formation of micelles and nanocrystals in the pyridine-based polymeric system was achieved upon prolonged UV irradiation at 250 nm. The TEM image of the micelles is presented in FIG. 4B, while that of the nanocrystals is presented in FIG. 4C.

The micelles with the size in the range of 200 nm and the nanocrystals with the average size 20-30 nm are two kinds of the phase-separated structures, which also characterized the gel after UV-irradiation. The electron diffraction pattern of the typical nanocrystal clearly indicates the concentric ring diffraction pattern and Bragg spots.

Under UV-irradiation centered at 250 nm or 380 nm, poly-(vinyl pyridine)/pyridine/water solution change conductivity depending on the composition contents and the thickness of the composition layer. Most probable explanation of the phenomenon is in the photoinduced free and bounded pyridine ordering through the photoinduced proton transfer between neutral pyridine and pyridinium as free as bounded with formation of the conductive channels in a case of irradiation with 380 nm and covalent bonding in a case of irradiation with 250 nm.

The conducting properties of the polymer solutions of the present invention before and after UV-irradiation were compared. To evaluate the conducting properties, the following three methods were used.

Current measurement in the circuit. In this method, the composition (polymer solution) was placed in the cell constructed from two slides: quartz slide covered by a gold layer (thickness 0.4 μm with OD 0.6-0.7 at 380 nm) and glass slide covered with ITO. The Sweep Function Generator (Escort) was used as a source of voltage (10 Hz, 3,6 V) to avoid electrode polarization, and Keithley 237 and model 197 was used as a current source.

Cyclic voltammetry (CV) measurement (I. Turyan, D. Mandler, J. Am. Chem. Soc., 1998 (120, pp. 10733-10742) in a range of −1.0+1.0 V.

I-V dependence by application of the Source-Measurement Unit Keithley 237.

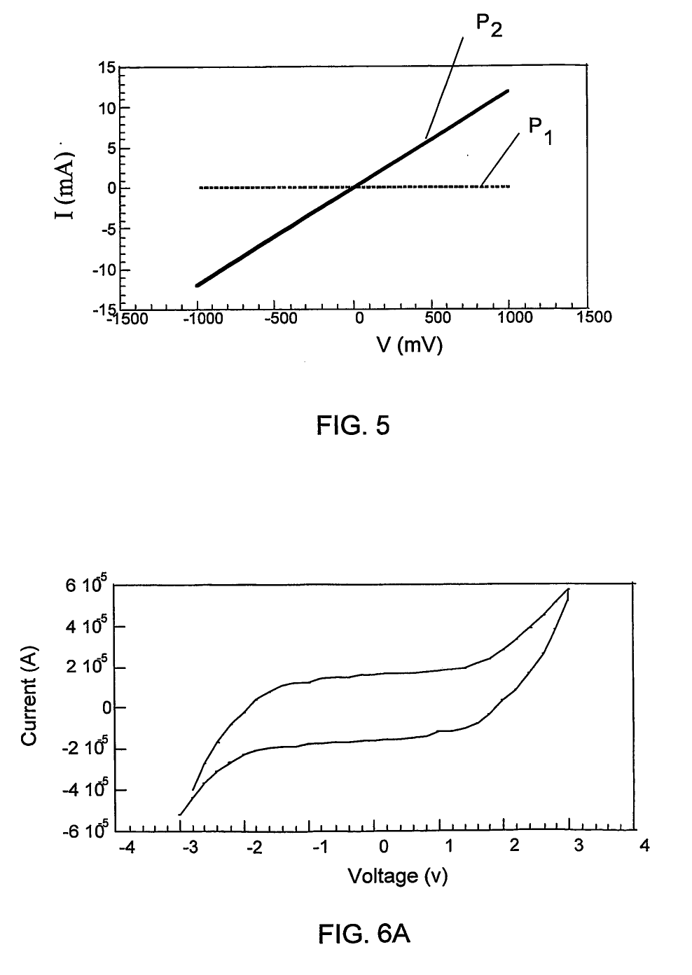

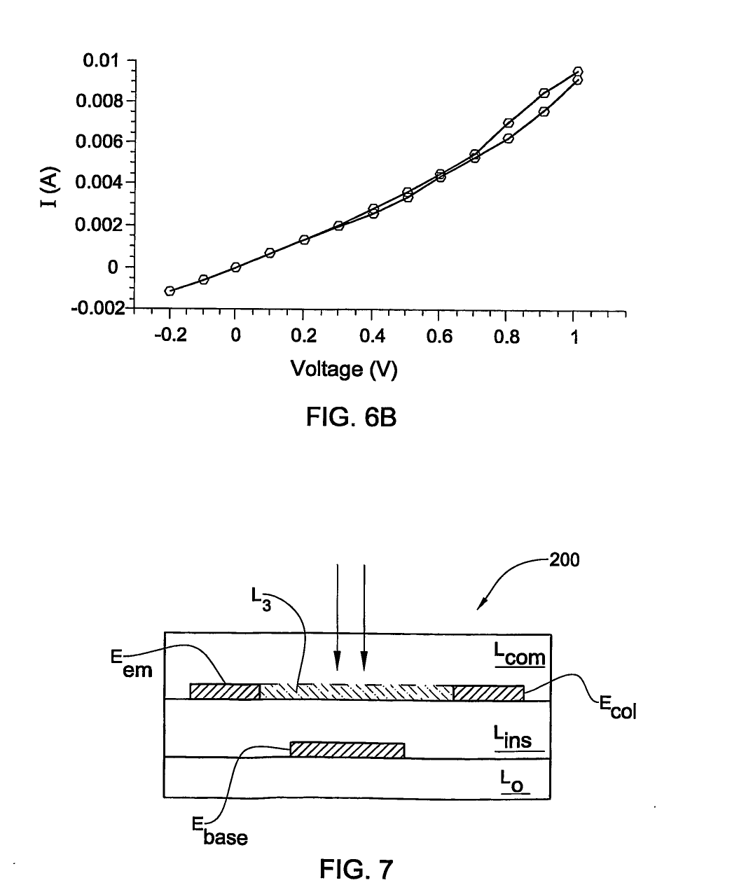

FIGS. 5, 6A-6B graphically illustrate the results of the above experiments. As shown in FIG. 5 (results of method B with V vs Ag/AgCl electrodes), before irradiation (graph P₁), the conductivity of the 20 μm film of poly(4-vinylpyridine)/pyridine/water was 1.2×10⁻⁸ Scm⁻¹. After UV-irradiation (graph P₂) with a wavelength of 380 nm during 30 min, the conductivity increased to 0.8×10⁻⁴ Scm⁻¹. This electric conductivity of the film was stable during 12 months period of storage. Conductivity of 10⁻⁶ Scm⁻¹ was obtained when a similar film with a thickness of about 3 μm was irradiated with 250 nm radiation.

FIG. 6A shows the I-V dependence (measured with method C) of the thin film of poly(4-vinylpyridine)/pyridine/water (Cr—Au/ITO-electrodes) before the application of UV-radiation. The initial conductivity (before irradiation) was evaluated as 2.3×10⁻⁶ Scm⁻¹. Slight ionic conductivity characterizes the conductivity properties of the film. FIG. 6B illustrates the I-V dependence of the same film after 1 hour of the 380 nm wavelength UV-irradiation (Cr—Au/ITO electrodes). The conductivity of the film was estimated as 7×10⁻³ Scm⁻¹. When using a laser source with power of the beam in the range of W/cm², it is possible to achieve the same conductivity change with the irradiation duration of microsecond scale.

The average value (43 experiments) of the conductivity before irradiation of the polymer solution thin film of poly(4-vinylpyridine)/pyridine/water was estimated as 2.5×10⁻⁸ Scm⁻¹. The average value (23 experiments) of the conductivity change in the case of the long wave range of UV irradiation (380 nm) was estimated as 6.3×10⁻⁴ Scm⁻¹. The average value (20 experiments) in the case of the short wavelength UV-irradiation (250 nm) was estimated as 7.2×10⁻⁵ Scm⁻¹.

Additionally, the experiments have shown that increasing the content of water in the composition decreases the initial conductivity thereof (i.e., prior to being irradiated by UV-radiation).

The following polymer/solvent compositions were tested (method A) on the photoinduced conducting properties:

1. (a) Poly(2-vinyl pyridine)/EtOH and (b) Poly(2-vinyl pyridine)/Py;

2. (a) Poly vinyl pyrrolidone/EtOH and (b) Poly vinyl pyrrolidone/Py;

3. (a) Poly(4-vinyl pyridine-co-butylmethacrylate)/EtOH and (b) Poly(4-vinyl pyridine-co-butylmethacrylate)/Py and

4. (a) Poly(4-vinyl pyridine)/EtOH and (b) Poly(4-vinyl pyridine)/Py.

TV-irradiation of the compositions 1(a) and 1(b) resulted in the conductivity change by the factors of 0.91 and 1.2, respectively. Irradiation of the compositions 2(a) and 2(b) resulted in the conductivity change by factors 1.25 and 1.05, respectively. Irradiation of the compositions 3(a) and 3(b) provided the conductivity changes by factors 1 and 17.1, respectively. The similar treatment of the composition 4(a) provided the conductivity increase by factor of 1.38. Poly(4-vinyl pyridine)/Py (composition 4b) showed the conductivity change from 3.6×10⁻⁸ Scm⁻¹ before irradiation to 1.8×10⁻⁵ Scm⁻¹ after irradiation (ratio of 5000).

The composition of the present invention can thus be used, for example, in electrophotography, serving as a photoreceptor on which a latent electrostatic image (charge pattern) can be created by applying UV-radiation, for example 250 nm, to corresponding locations in the composition.

The composition of the present invention can also be used in a transistor device. FIG. 7 schematically illustrate a transistor structure 200 fabricated by integrated technology to define three electrodes—base electrode E_{base} located on top of a substrate layer L₀ and coated by an insulating layer Lᵢₙₛ (SiO₂), emitter and collector electrodes Eₑₘ and E_{col} arranged in a spaced-apart relationship on top of the insulating layer and coated by the composition L_{com} of the present invention. A semiconductor region Rₛₑₘ in a space between the electrodes Eₑₘ and E_{col} is then created by irradiating the respective location in the composition with a 380 nm radiation.

The composition of the present invention can also be used in photoinduced non-linear optic (NLO) devices. NLO waveguides can be defined by UV irradiation, and OLEDs' 480 nm emission can be turned to 515 nm wavelength by irradiation with UV-light at 380 nm. The emission wavelength of the device can be altered in real time by UV irradiation.

Those skilled in the art will readily appreciate that various modifications and changes can be applied to the embodiments of the invention as herein before exemplified without departing from its scope defined in and by the appended claims.

1. An organic composition comprising a water-soluble heteroaromatic compound, and a polymer containing repeat units derived from six-membered aromatic heterocyclic monomers substituted in the 4-position relative to the heteroatom by an alkyl substituent, said six-membered aromatic heterocyclic monomer optionally being further substituted, the organic composition being characterized in that it also comprises water such that the molar ratio between the polymer, the water-soluble heteroaromatic compound and water is about 1:1:(0.3-1.0), the composition being excitable by predetermined incident electromagnetic radiation of predetermined intensity such that the excitation of a location of the composition by the predetermined incident radiation creates at least one of the following effects: a desired luminescence of the excited location and a desired electrical conductivity of the excited location.

2. The composition according to claim 1, being excitable by the predetermined electromagnetic radiation in the ultraviolet or visible spectrum range.

3. The composition according to claim 1, being excitable by the predetermined electromagnetic radiation having a wavelength selected of about 250 nm.

4. The composition according to claim 1, being sequentially excitable by the electromagnetic radiation of at least two different wavelengths, resulting in the at least one of desired luminescence and desired conductivity of the sequentially excited location in the composition.

5. The composition according to claim 1, being excitable by the predetermined electromagnetic radiation to be shiftable between different states of at least one of the desired luminescence and desired electrical conductivity.

6. The composition according to claim 1, wherein the excited location of the composition is responsive to the predetermined electromagnetic radiation to be thereby returned to its passive, non-luminescent state.

7. The composition according to claim 1, having an initial conductivity, prior to applying the electromagnetic radiation thereto, of about 10⁻⁹ Scm⁻¹.

8. The composition according to claim 1, wherein said desired conductivity is in a range between 10⁻⁶-10⁻³ Scm⁻¹.

9. The composition according to claim 1, wherein said water-soluble heteroaromatic compound is selected from the group comprising: pyridine, substituted pyridine, pyrimidine, nicotine, quinoline, substituted quinoline, adenine, bi-pyridine, derivatives thereof and mixtures thereof.

10. The composition according to claim 1 wherein said polymer is selected from optionally substituted poly(4-vinyl pyridine), poly(4-vinyl quinoline) and co-polymers thereof.

11. An organic composition according to claim 1, comprising poly(4-vinyl pyridine), pyridine and water in a molar ratio of about 1:1:(0.3-1.0), the organic composition being responsive to incident electromagnetic radiation of a predetermined wavelength range such that irradiation of a location of the composition creates a desired electrical conductivity of said location.

12. A composition according to claim 1, being excitable by the predetermined incident electromagnetic radiation between its passive non-luminescent state and active luminescent state, and vice versa.

13. An optical device comprising a cell containing an organic composition according to claim 1, said cell being shiftable between stable states of different responses of said composition to predetermined incident electromagnetic radiation.

14. The device according to claim 13, being operable as an optical switch.

15. The device according to claim 13, being an information carrier.

16. A transistor structure having an electrodes' arrangement and the composition of claim 1 located in a space between the electrodes, a semiconductor region of the transistor being the excited location in said composition.

17. A method for treating an organic composition comprising a water-soluble heteroaromatic compound, water, and a polymer containing repeat units derived from six-membered aromatic heterocyclic monomers substituted in the 4-position relative to the heteroatom by an alkyl substituent, said six-membered aromatic heterocyclic monomer optionally being further substituted, wherein the molar ratio between the polymer, the water-soluble heteroaromatic compound and water is about 1:1:(0.3-1.0), the method comprising:
(i) providing a viscous mixture of the constituents as defined above;
(ii) irradiating at least selected locations of said viscous mixture with ultra-violet radiation having a predetermined intensity so as to cause excitation in the irradiated locations of said mixture to thereby obtain at least one of desired luminescence or desired electrical conductivity of the irradiated locations.

18. The composition according to claim 1, wherein excitation by electromagnetic radiation having a wavelength of about 250 nm, results in the formation of aminopentadienal and/or polyazaacetylene in that composition.
